(19) United States
(12) Patent Application Publication
(10) Pub. No.: US 2010/0074003 A1
(43) Pub. Date: Mar. 25, 2010

(54) Single conductor magnetoresistance random access memory cell

(76) Inventor: Klaus Schroder, E. Syracuse, NY (US)

Correspondence Address: KLAUS SCHRODER, 7226 COVENTRY Rd. N., E. SYRACUSE, NY, 13057, US

(21) Appl. No.: 12/284,453

(22) Filed: Sep. 22, 2008

(51) Int. Cl. G11C 11/02

(52) U.S. Cl. 365/171

(57) ABSTRACT

The single conductor magnetoresistance random access memory consists of memory cells which are made up of a flat thin film conductor, covered on both flat surfaces with thin magnetic films. Their coercive forces have different values. A current flowing through the conductor produces a magnetic field which circles the conductor. For high currents, which lead to magnetic fields larger than the coercive force of each of the magnetic films, the two magnetic films will be magnetized antiparallel to each other. Current values which produce magnetic fields between the values of the coercive field values of both films, will only modify the magnetization direction of the film with the low coercive field. It can be lined up parallel- or anti-parallel to the magnetization of the high coercive force film without changing the magnetization direction of the high coercive film. For materials which show the giant magnetoresistance effect, the resistance of the conducting film for parallel line-up of the magnetoresistance direction will differ noticeably from the resistance for a antiparallel line-up. Currents so low that the magnetic field generated around the conducting film is below the coercive fields will not change the magnetization direction even in the film with the low coercive field. Such a current can be used to measure the resistance of the memory element without destroying the information. It leads to a non-destructive read out.

### BACKGROUND OF INVENTION

1) Field of Invention

The present invention deals with a new form of a magnetic random access memory (MRAM) which is operated by the flow of a current in only one central thin film conductor.

2) Description of Related Art

Magnetic computer memories exist in many forms. One of the best know is the hard disk drive in which the information is stored in magnetic films (or layers) deposited on metallic disks. Another magnetic memory is the magnetic core memory. This consists of a large number or magnetic rings. Each magnetic ring (or core) is magnetized either clockwise or anticlockwise. One orientation corresponds to a ‘0’, the other to a ‘1’. This shows how each core stores one “bit” of information. The read-out is destructive. The magnetic memories are non-volatile.

One disadvantage of the core magnetic memory is that the size of one core is rather large. Therefore new forms of magnetic memories have been developed. One is the Magnetic Random Access Memory (MRAM). Here the magnetic core is replaced by a group of small magnetic films and conducting wires or films. This represents a “Memory Cell” which can store one “bit” of information. In a typical example, the memory cell consists of a magnetic substrate, a first electrical conductor on top of it, and a second magnetic film on top of the conductor. A second conducting wire or film is placed on top on the second magnetic film.

These units are lined up in rows so that the first electrical conductor passes through a row of memory elements. Large numbers of these rows are lined up parallel to each other. The second conducting wires are arranged so that each passes through a column of Memory Cells. The columns of lines of the second conducting wires are lined up perpendicular to the lines of the first rows of conductors.

The operation of this arrangement of magnetic cells is similar to the operation of a magnetic core memory. By picking the two conductors which pass through one memory cell, and by selecting the appropriate currents, one can arrange the magnetization direction in the substrate magnetic and top magnetic film in such a way that they are parallel or antiparallel to each other. Parallel magnetization leads to a low resistance in the middle conductor film, antiparallel orientation to a higher resistance. Resistance changes can be large if one uses the ‘giant magneto resistance effect’ or ‘the tunneling magneto resistance effect’.

This memory is non-volatile.

### BRIEF SUMMARY OF INVENTION

The present invention differs from previous MRAMs because it uses only one conductor to magnetize the magnetic films of each magnetic cell. The bottom film (film 1) in the magnetic cell is a ferromagnetic film with a coercive field H_{c}(1); the middle film (film 4) is an electrically conducting film; and the top film (film 7) is another magnetic film with a coercive field H_{c}(7). The films are prepared in such a way that H_{c}(7) is smaller than H_{c}(1).

A current through the middle film (film 4) is used to magnetize the films 1 and 7 in the desired directions, and is also used for the resistant measurement in the middle film 4 to check if its resistance is low (this may correspond to ‘0’) or high (which may correspond to a ‘1’). Sending a current with a magnetic field larger than H_{c}(1) through film 4 will magnetize the moment in film 1 in a specific direction. It will also magnetize film 7 in the opposite direction. However, if one wants to line up the magnetization direction in film 7 parallel to the magnetization direction in layer 1, one has to select a current which produces a magnetic field with values between H_{c}(1) and H_{c}(7). This current flows in the opposite direction of the current which was used earlier to line up the magnetization direction in film 1. ‘Reading’ the memory element will be done as in previous MRAMs by measuring the resistance of film 4 with a current which has a magnetic field smaller than H_{c}(7).

### BRIEF DESCRIPTION OF THE DRAWINGS

FIG. 1 shows the magnetic unit cell. It consists only of one conductor, film 4, and two magnetic films, film 1 and 7, adjacent to the conductor.

FIG. 2 shows a Magnetic Cell with a multilayer construction. The bottom film 1 is made of a magnetic material, with the coercive field H_{c}(l). On top of this, an insulating film 2 is formed, followed by a semiconducting film 3, the electrical conductor film 4, another semiconducting film 5, another insulating film 6, and a magnetic film 7 with the coercive field H_{c}(7).

FIG. 3 shows how this Magnetic Cell (numbers 1 to 7) is connected through film 4 to an electronic switch 10 with its connectors 8 and 9. The Memory Cell and the electronic switch form together the Memory Element.

### DETAILED DESCRIPTION OF THE DRAWINGS

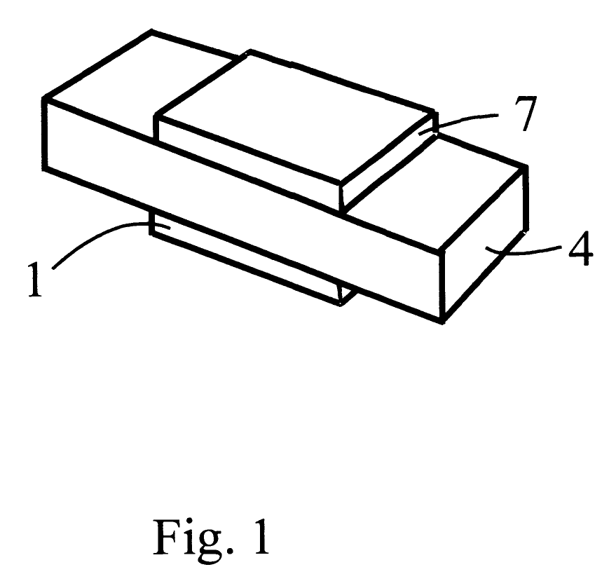

FIG. 1 shows the Magnetic Cell. It consists of a thin film conductor, film 4, which is surrounded by two ferromagnetic or ferrimagnetic thin films 1 and 7. The width of the magnetic layers may be smaller than the width of the conductor, and they may be of irregular shape.

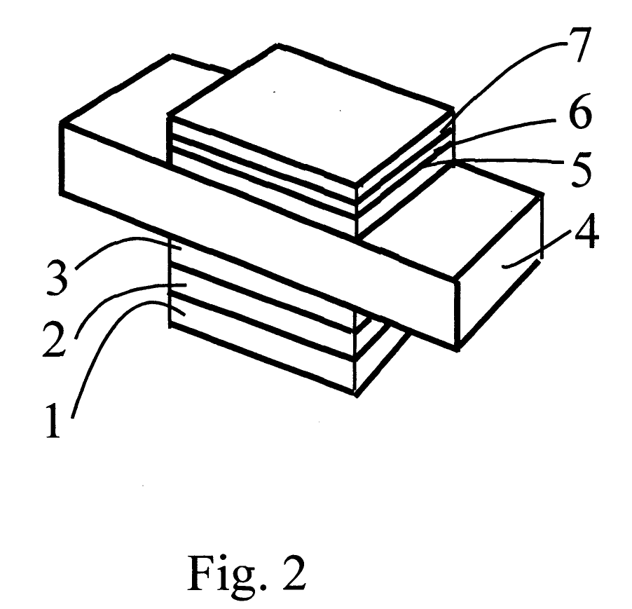

FIG. 2 shows a magnetic unit cell which consists of 7 layers, a first magnetic film 1 with coercive field H_{c}(1), an insulating film 2, a thin semiconducting film 3, which may be a few atomic layers thick, a central conducting film 4, which may be about 10 nm thick and 100 nm wide. These numbers are picked just for illustration. On top of this conductor is another semiconducting film 5, followed by the insulating film 6. Finally, a second magnetic film, film 7, is deposited on the insulating film 6.

The magnetic films may be made of different materials, have different thicknesses, and their shapes may deviate from an approximately rectangular shape shown in FIGS. 1 and 2. This will lead to different coercive field. Instead of one square, the film can also consist of several thin stripes. The magnetic shape anisotropy would tend to line up the magnetization in the direction of the long axis of the stripe. The stripes don't have to be lined perpendicular to the current (or parallel to the direction of the magnetic field). If they are lined up inclined to this direction, their magnetization direction will, after the magnetic field is turned off, be lined up in the direction of the long axis of the stripe if the shape anisotropy controls the magnetization direction. It will have components of the magnetization which are lined up in the direction of the current and perpendicular to the current. This could strengthen the magnetoresistance effect.

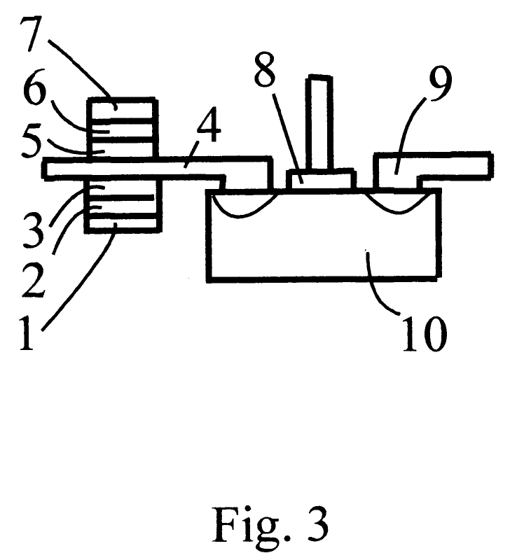

FIG. 3 shows the Memory Element, which consists of the Magnetic Cell, and an electronic switch 10 in the form of a field effect transistor. One end of the conductor of the magnetic unit cell, film 4, may be connected to a word or bit line, the other end may be connected to the drain or source of the field effect transistor which may be connected through conductor 9 to a common ground. The gate of the transistor may be connected with connector 8 to a bit-line. One can reverse the direction of the field effect transistor. Other forms of connections between the Magnetic Cell, the switch, bit- and word-lines can be easily envisioned by anyone familiar with the art.

### DETAILED DESCRIPTION

### A) Magnetic Fields

The magnetic field H around an electrical conductor can be calculated easily only for a simple case like a rod with a circular cross section. The conductor in the Magnetic Cell is a very thin conductor with a rectangular cross section. The magnetic field due to a current in this conductor has a complicated spacial distribution. If the film would have a thickness d and would be infinitely long and wide, then the magnetic field H would be equal to H=j·d/2, with j the current density in the film. The direction of H would be parallel to the film surface and perpendicular to the current direction.

This equation should give a first approximation for the magnetic field generated near the film surface by a current in a thin film conductor. Let us assume just as an illustration that the film is 10 nm thick with a width of 100 nm and a length between bit-line and electronic switch of 200 nm. Let us further assume that the film resistivity is 2E-6 Ohm.·m and that a voltage of 0.4 mV is applied along the 200 nm length of the film. The resistance is 400 Ohm, and the current 0.1 mA. The magnetic field is H=50 A/m. This corresponds to about 0.625 Oe. This field should be large enough to operate the Magnetic Cell, since materials with much smaller coercive fields exist. For instance, the coercive field H_{c} for purified iron is about 0.05 Oe, and for Supermalloy, H_{c} is about 0.002 Oe. Other combinations of film dimensions and applied voltages are possible; and their magnetic fields can be easily estimated with the equation for the magnetic field given above.

B) Magnetic Film with Fixed Magnetization Direction.

In another version of the system, the magnetic films with the high coercive force in a Magnetic Cell are selected in such a way that their magnetization is magnetized permanently in a specific direction. This could be done by selecting a suitable ferro- or ferrimagnetic material with a high magnetic coercive field, or depositing an antiferromagnetic film on the magnetic film, after it was magnetized in the preferred orientation. Naturally, one can also limit the current in such a way that it never provides magnetic field which can change the magnetization direction in the film with the high coercive field. Only the magnetization direction of the magnetic film with the lower coercive field will be changed in this version of the Memory Cell to store information.

### C) Semiconducting and Insulating Films.

In one version of the device, a semiconducting film 3 is placed in between films 1 and 4; another semiconducting film 5 is placed between layers 4 and 7. The semiconducting films can reduce the electrical resistance of the unit, since they reduce non-elastic electron scattering on the conductor-semiconductor interfaces if films are prepared under very clean conditions. In this case the surfaces during film production are clean. Metastable surface bonds at the surface will break when the next layer grows and will produce clean bonding between layers. It has been shown that depositing copper on ultra thin Ge-substrates produces films which have resistance/square values of about 4 micro Ohm meter for 1 nm thick Cu-films. It is less than 1 micro Ohm meter for a film 3 nm thick. A further advantage is, that the semiconducting layer reduces the current flow through the ferromagnetic films

Thin insulating films 2 and 6 will also prevent or reduce current flow into the ferromagnetic films. This will reduce the current needed to change the magnetization direction in the magnetic films.

### D) Connection of Components.

One end of the conductor of the magnetic unit cell is connected to a word or bit line and the other end to the drain of the field effect transistor. The source of the field effect transistor is connected to a common ground and the gate to a bit or word line. This arrangement may lead to a system in which the total resistance of the magnetic cell and the field effect transistors has a different resistance if the current flow direction through the system is reversed. This problem can be avoided if one uses a pair of field effect transistors, placed antiparallel to each other so that the end of the conductor not connected to the word or bit line is connected to the source of the first transistor and to the drain of the second transistor. The drain of the first transistor and the source of the second transistor are connected to the common ground, and the gate of both are connected to the same bit or word line. Other arrangements can be easily visualized

Instead of the field effect transistor, one can use a bipolar junction transistor. Any electronic switch can be used to control the current through the Magnetic Memory Cell.

Modifications and advantages will be apparent to those skilled in the art. The invention is not limited to the details of the specifications. Therefore modifications may be made without departing from the spirit or scope of the general inventive concept as described in the claims and their equivalents given below.

What is claimed is:

1) A magnetic random access memory with a Memory Element comprising:
a.) a Magnetic Cell and an electronic switch, in which the Magnetic Cell consists of a thin film conductor between two magnetic layers with different coercive fields, and in which
b) the current in the conductor is used to produce a magnetic field which is larger than the coercive field of each magnetic film to magnetize the magnetic film with the higher coercive field in the desired direction, which will at the same time line up the magnetic direction in the magnetic film with the lower coercive field in the opposite direction so that both magnetic films are magnetized antiparallel to each other if desired, and then
c) to use an electric current which produces a magnetic field with a value between the coercive fields of the magnetic fields to magnetizes the magnetic film with the lower coercive field into a new preferred direction if desired, and in which
d) a current with a magnetic field lower than the coercive field of both magnetic films is applied to measure the electrical resistance of the central conducting film to determine if the magnetization directions of the two magnetic films are lined up parallel or antiparallel to each other, giving so the stored information.

2) A Memory Element as in claim 1 in which the electronic switch is a transistor

3) A Memory Element as in claim 2, in which the electronic switch is a field effect transistor.

4) A Magnetic Cell according to claim 1 in which the magnetic films are smaller in width than the electrical conductor.

5) A Magnetic Cell according to claim 1 in which the magnetic films consists of small stripes

6) A Memory Element according to claim 3, in which one end of the conductor of the Magnetic Cell is connected to a word-line, and the other end to two field effect transistors in such a way that it is connect to the first field effect transistor to the drain, in the second to the source, and in which the source of the first transistor and the drain of the second transistor are connected to a common ground, and both gates are connected to the same bit-line.

7) A Memory Element according to claim 2, in which the switch is a bipolar junction transistor.

8) a Memory Element as in claim 1 in which the magnetic layers of the Magnetic Cell are separated from the electrical conductor by thin semiconducting or insulating layers or both to reduce interface scattering on the surface of the conductor, and to reduce the current flow in the magnetic layers to very low values, including zero values.

9) A Memory Element as in claim 8 in which the electronic switch is a transistor.

10) A Memory Element as in claim 9, in which the electronic switch is a field effect transistor.

11) A Memory Element according to claim 8 in which the magnetic films of the Magnetic Cell are smaller in width than the electrical conductor, and are of irregular shape.

12) A Memory Element as in claim 8 in which the semiconducting films are Ge or Si.

13) A Memory Element as in 8 in which the magnetic films are thin long stripes.

14) A Memory Element according to claim 8, in which one end of the conductor is connected to a word-line, and the other to two field effect transistors in such a way that it is connect in the first field effect transistor to the drain, in the second to the source. The source of the first transistor and the drain of the second transistor are connected to a common ground, and both gates are connected to the same bit-line.

15) A Memory Element as in claim 9, in which the electronic switch is a bipolar junction transistor.
